(19) United States
(12) Patent Application Publication
(10) Pub. No.: US 2012/0032229 A1
(43) Pub. Date: Feb. 9, 2012

(54) Silicon Wafer And Production Method Thereof

(75) Inventors: Hiroyuki Deai, Hikari (JP); Seiji Takayama, Hikari (JP)

(73) Assignee: SILTRONIC AG, Munich (DE)

(21) Appl. No.: 13/191,532

(22) Filed: Jul. 27, 2011

(30) Foreign Application Priority Data
Aug. 9, 2010 (JP) 2010-178928

(51) Int. Cl. H01L 29/165; H01L 29/36

(52) U.S. Cl. 257/190; 257/E29.085; 257/E29.109

(57) ABSTRACT

A silicon wafer contains: a silicon substrate; a first epitaxial layer on the silicon wafer, wherein the absolute value of the difference between donor and acceptor concentrations is ≧1×10¹⁸ atoms/cm³; a second epitaxial layer above the first epitaxial layer, whose conductivity type is the same as the first epitaxial layer, wherein the absolute value of the difference between donor and acceptor concentrations is ≦5×10¹⁷ atoms/cm³; wherein, by doping a lattice constant adjusting material into the first epitaxial layer, the variation amount ((a₁-a_{Si})/a_{Si}) of the lattice constant of the first epitaxial layer (a₁) relative to the lattice constant of the silicon single crystal (a_{Si}) as well as the variation amount ((a₂-a_{Si})/a_{Si}) of the lattice constant of the second epitaxial layer (a₂) relative to the lattice constant of the silicon single crystal (a_{Si}) are controlled to less than the critical lattice mismatch.

### CROSS-REFERENCE TO RELATED APPLICATIONS

This application claims priority to Japanese Patent Application JP2010-178928 filed Aug. 9, 2010 which is herein incorporated by reference.

### BACKGROUND OF THE INVENTION

1. Field of the Invention

The present invention relates to the technical field of silicon wafers used for semiconductor devices. Particularly, the present invention relates to a technology to prevent misfit dislocations that occur within silicon wafers that incorporate an epitaxially grown film.

2. Background Art

Currently, silicon wafers used in semiconductor devices are required to have a denuded zone as well as a high gettering capability in a device active region on its surface layer.

As an example that satisfies those requirements, epitaxial wafers that use a highly doped substrate are known. An example of such wafers includes a p/p+ substrate. The p/p+ substrate is manufactured by producing a p+ substrate containing a boron concentration of roughly 5×10¹⁹ atoms/cm³ and subjecting the p+ substrate to mirror polishing as well as cleaning, and then epitaxially growing a 5 um thick device active layer on the mirror polished p+ substrate by vapor phase epitaxy, wherein the device active layer is doped with a relatively low boron concentration of approximately 1×10¹⁵ atoms/cm³.

An n/n+ substrate is used for power MOSFETs, etc. The n/n+ substrate utilizes an n+ substrate which is highly doped with an n-type dopant such as phosphorus or arsenic. An n-type epitaxial layer which is doped with a relatively low phosphorus concentration of approximately 1×10¹⁶ atoms/cm³ is deposited on this n+ substrate to form the n/n+ substrate.

Also, IGBTs often have a structure created by depositing a doped silicon layer with an n-type dopant on a p-type substrate, and further depositing a doped silicon layer with a low-concentration of n-type phosphorus on the doped silicon layer with an n-type dopant. The p-type substrate is doped with a high boron concentration. The doped silicon layer is a silicon layer doped with a high-concentration of n-type dopant greater than or equal to 1×10¹⁷ atoms/cm³ which is intended to stop expansion of the depletion layer. The concentration of the uppermost n-type lightly doped layer is controlled within the concentration from 1×10¹³ atoms/cm³ to 1×10¹⁵ atoms/cm³, depending on its gate oxide integrity.

The surface layer deposited by epitaxial growth is defect-free. Heavy metals accumulated during device processes, in particular Fe contamination, are strongly gettered. Since the yield ratio of devices is improved, epitaxial wafers using these highly doped substrates have been used widely for the semiconductor devices.

However, for the aforementioned wafers, misfit dislocations tend to occur at the interface between the substrate and the layer doped with a low concentration dopant, or at the interface between the low concentration epitaxial layer and the layer doped with a high concentration dopant, due to the variation in the lattice constant of the silicon crystal. Such misfit dislocations may propagate through the device active layer depending on its form.

Taking a vertical power MOSFET as an example, dislocations penetrating through the device active layer (also called threading dislocations) may also penetrate both into the drain on the underside and the source on the surface. This can cause leakage current between the source and the drain.

As for IGBTs, there is the possibility of leakage current between the collector and the emitter. Such leakage current may increase the power consumption of power devices on standby.

JP2004-175658 discloses a technology to prevent such misfit dislocations. JP2004-175658 discloses a method in which a silicon epitaxial layer is deposited on a boron- and germanium-doped silicon substrate which is grown by including both boron and germanium in the silicon melt. In this method, a certain amount of boron which decreases the lattice constant of a silicon crystal as well as germanium which increases the lattice constant of a silicon crystal are added to the silicon melt. The effect of decreasing the lattice constant by boron is offset by the effect of increasing the lattice constant by germanium. JP2004-175658 discloses that it is possible through this method to produce epitaxial silicon wafers in which the misfit dislocations are prevented.

JP2003-218031 describes another technology to prevent misfit dislocations. JP2003-218031 discloses formation of a SiC or GaN film by epitaxial growth onto the surface of an Si substrate. A zincblende type single crystal of BP (boron phosphide) is used as a buffer layer during growth, enabling prevention of misfit dislocations caused by lattice mismatches.

More specifically, BCl₃ and PCl₃ as the raw materials for BP are introduced into a reactor after removing the native oxide film of an Si substrate. Low-temperature growth at approximately 200-500° C. is performed for 30 minutes, following which the temperature is raised to 900-1200° C., the temperature required to grow a BP crystal, to grow a 1 to 5 μm thick BP film. Then, an SiC or GaN film is deposited on top of the BP film by the epitaxial method. Also, it is described that the amount of warpage of the whole semiconductor wafers can be controlled by forming a film made of SiO₂ or Si₃N₄ in addition to the SiC or GaN film. However, according to JP2003-218031, if a buffer layer is formed independently in order to prevent the misfit dislocations caused by lattice mismatches, a buffer layer does not function as a device.

Also, according to JP2004-175658, when forming a silicon substrate which is produced from a silicon melt doped with both germanium as well as a high concentration of boron, and then depositing an epitaxial layer doped with a certain concentration of germanium and boron on this silicon substrate, segregation of impurities such as a dopant arises as an unpreventable problem if the silicon substrates are grown by the Czochralski method. In addition, there is a large difference between the segregation coefficients of boron and germanium. Consequently, it is difficult to maintain a proper ratio of boron to germanium over the whole length of a crystal by the method described in JP2004-175658. It has thus been difficult for all substrates processed from a crystal derived from this method to resolve the lattice mismatch between the substrate and the epitaxial layer. In addition, the expensive germanium must be consumed in a large amount if the crystal is grown by the Czochralski method or by the zone melting method (FZ process) used in JP2004-175658. Thus, the production costs for wafers is increased.

The present invention has been completed as a result of intensive studies by the inventors in order to resolve the above problems.

### SUMMARY OF THE INVENTION

The present invention provides a silicon wafer structure with reduced misfit dislocations and warpage, by providing a silicon wafer structure comprising a silicon substrate, a first epitaxial layer, and a second epitaxial layer, the silicon substrate exhibiting a resistivity of greater than or equal to 0.1 Ω.cm, wherein the first epitaxial layer has an absolute value of the difference between the donor concentration and the acceptor concentration of greater than or equal to 1×10¹⁸ atoms/cm³, and the first epitaxial layer is grown on one surface of the silicon substrate, wherein the second epitaxial layer has an absolute value of the difference between the donor concentration and the acceptor concentration of less than or equal to 5×10¹⁷ atoms/cm³, and the second epitaxial layer is grown on the surface of the first epitaxial layer, and wherein the second epitaxial layer has the same conductivity type as the first epitaxial layer.

### BRIEF DESCRIPTION OF THE DRAWINGS

FIG. 1A is a schematic view of the structure of one embodiment of a silicon wafer of the present invention.

FIG. 1B is an enlarged schematic view of the interface between the epitaxial layer and the silicon substrate in the event of occurrence of misfit dislocations in the epitaxial wafer.

FIG. 2 is a schematic view of the structure of one embodiment of a silicon wafer of the present invention.

FIG. 3 is a schematic view of the structures of POWERMOSFET and IGBT.

### DETAILED DESCRIPTION OF THE PREFERRED EMBODIMENTS

The present invention does not utilize a substrate which was highly doped and formed by the conventional Czochralski method or by zone melting. The doped silicon layer with a high-concentration of impurity is totally formed by epitaxial growth instead. The lattice constant can be controlled properly by doping the lattice constant adjusting material into this doped silicon layer with a high-concentration impurity. Therefore, the lattice mismatch between a doped silicon layer with a low-concentration impurity and the interface can be avoided. Misfit dislocation or warpage can be also resolved.

A lattice constant adjusting material is added to the first epitaxial layer. Thereby, the variation amount ((a₁-a_{Si})/a_{Si}) of the first epitaxial layer's lattice constant (a₁) relative to the silicon single crystal's lattice constant of (a_{Si}) as well as the variation amount ((a₂-a_{Si})/a_{Si}) of the second epitaxial layer's lattice constant (a₂) relative to the silicon single crystal's lattice constant of (a_{Si}) can be controlled to less than the critical lattice mismatch.

In the present invention, the lattice constant adjusting material is doped during epitaxial growth. Thus, the problem of the inhomogeneous concentration when doping a dopant (e.g. germanium, boron, etc.) in conventional liquid phase growth can be prevented.

The present invention can be utilized for power MOSPET usages. The layer with a high dopant concentration has preferably a low resistivity to reduce ON resistance, and the present invention can achieve even lower resistivity compared to a substrate with a high dopant concentration produced by conventional liquid phase growth.

A first aspect of the present invention is a wafer comprising a silicon substrate, a first epitaxial layer, and a second epitaxial layer. The silicon substrate has a resistivity of greater than or equal to 0.1 Ω.cm. The first epitaxial layer has an absolute value of the difference between the donor concentration and the acceptor concentration of greater than or equal to 1×10¹⁸ atoms/cm³, and is grown on a surface of the silicon substrate. The second epitaxial layer has an absolute value of the difference between the donor concentration and the acceptor concentration of equal or to less than 5×10¹⁷ atoms/cm³, is grown on the surface of the first epitaxial layer, and has the same conductivity type as the first epitaxial layer.

A lattice constant adjusting material is added to the first epitaxial layer.

Therefore, the variation amount ((a₁-a_{Si})/a_{Si}) of the lattice constant of the first epitaxial layer (a₁) relative to the lattice constant of the silicon single crystal (a_{Si}) as well as the variation amount ((a₂-a_{Si})/a_{Si}) of the lattice constant of the second epitaxial layer (a₂) relative to the lattice constant of the silicon single crystal (a_{Si}) are controlled to less than the critical lattice mismatch. Thereby, the problems of misfit dislocations or warpages can be resolved.

In the present invention, the lattice constant adjusting material is doped during epitaxial growth. Accordingly, the problem of a concentration inhomogeneity in doping a dopant (including a lattice constant adjusting material) in conventional liquid phase growth can be prevented.

JP2006-080278 and JP2006-024728 disclose that to prevent threading dislocations caused by lattice mismatches, a silicon epitaxial layer which contains germanium as a lattice constant adjusting material is formed on the surface of the silicon substrate, and the germanium concentration is reduced from the interface between the silicon substrate and the epitaxial layer gradually or in a stepwise manner.

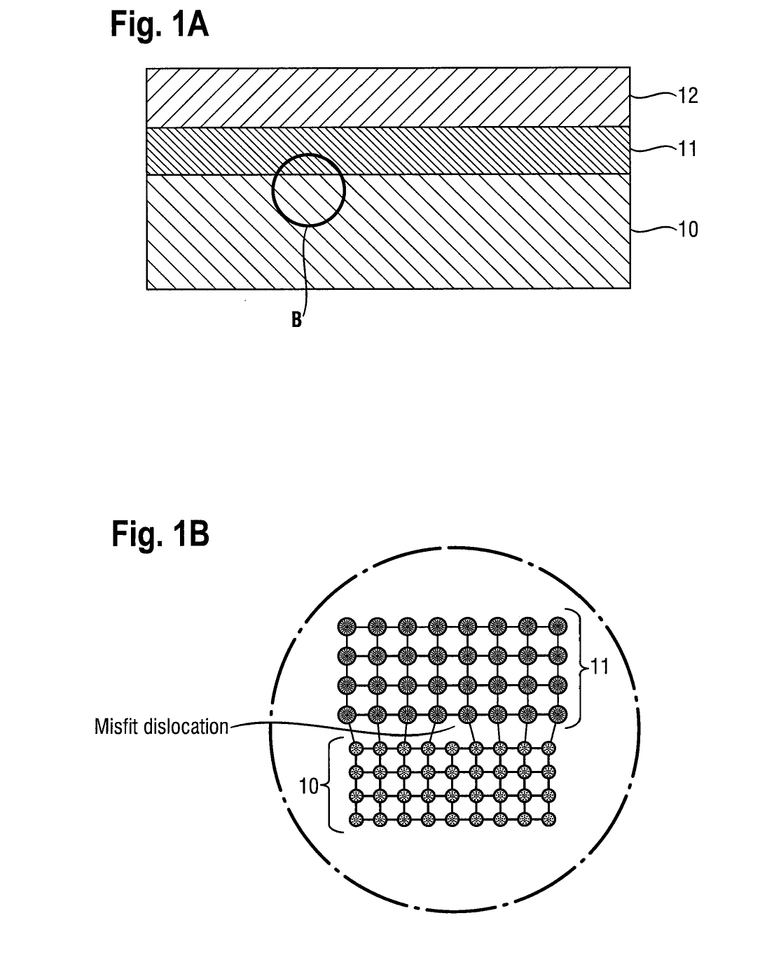

However, neither of these methods can prevent misfit dislocations. As described in JP2006-86179, misfit dislocations can occur even when nitride films are placed between a plurality of the silicon epitaxial layers which include germanium whose concentration is varied gradually or in a stepwise manner (JP2006-86179, FIG. 1). According to these methods in which the germanium concentration is varied gradually or in a stepwise manner, the germanium concentration can only be raised by 10% each time the silicon epitaxial layer containing germanium is grown in 1 μm thickness. For example, in order to form an epitaxial layer with 30% germanium concentration, it is necessary to grow as thick as 3 μm. It takes almost 1 hour at the usual speed of forming an epitaxial layer (approximately 0.1 nm/s). Thus, the productivity is low.

However, the present invention properly controls the lattice constant of the epitaxial layer without varying the germanium concentration in a stepwise manner. Therefore, the growth speed is not affected greatly. Referring to the appended figures, the silicon wafers relevant to the present invention will be explained below.

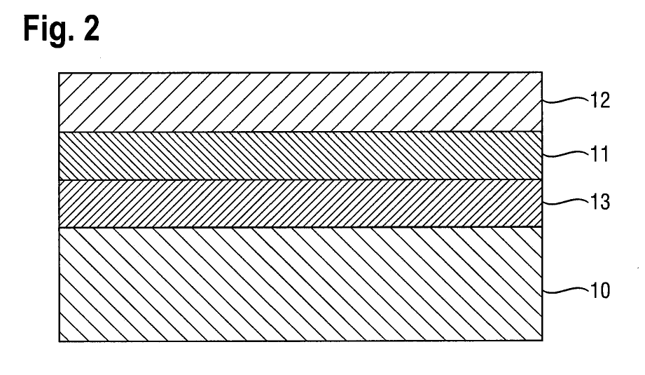

FIG. 1(A) is a schematic diagram showing an example of a semiconductor substrate according to a preferred embodiment of the present invention. First, a silicon wafer relevant to the present invention has the structure shown in FIG. 1(A). A first epitaxial layer 11 (n-type or p-type) is grown on a silicon substrate (e.g. nondope, n-type or p-type silicon single crystal) 10 by epitaxial growth. The first epitaxial layer 11 contains a lattice constant adjusting material as well as a donor and/or an acceptor. A second eptaxial layer 12 which contains the same conductivity type of the donor and/or an acceptor as the first epitaxial layer is further grown on the first epitaxial layer by epitaxial growth. A third p-type epitaxial layer 13 containing a lattice constant adjusting material and a donor and/or an acceptor can be provided between the first epitaxial layer 11 and the silicon substrate 10 as described later referring to FIG. 2.

Referring to FIG. 1(B), the interface between the silicon substrate 10 and the first epitaxial layer 11 will be explained as an example. If there is a large difference in the lattice constants between the silicon substrate 10 and the first epitaxial layer 11, stress due to the misfit dislocations acts upon the first epitaxial layer.

As the epitaxial growth further continues, the variation amount of the lattice constant of the first epitaxial layer exceeds the critical level, also referred to as a critical lattice mismatch, or the thickness of the first epitaxial layer 11 exceeds the critical film thickness. This causes defects in the crystal such as lattice mismatches (misfit dislocations) that act as to relax the above-mentioned stress, as shown in FIG. 1(B).

However, the growth of the epitaxial layer continues as long as the variation amount of the lattice constant of the first epitaxial layer does not exceed the critical level, that is, the thickness of the first epitaxial layer is thin enough. Even though lattice mismatches occur insubstantially, the epitaxial layer grows since the continuity of the lattice is preserved at the interface due to the deformation of the lattice of the epitaxial layer (“coherent growth”).

To explain in detail on the variation amount relevant to the present invention, the variation of the lattice constant can be expressed in Equation (1).

Δa/a=β×N Equation (1)

wherein “a” is the lattice constant, “Δa” is the variation of the lattice constant, “N” is the concentration of impurities (atom/cm³), “β” is a proportionality coefficient (cm³/atom), and “Δa/a” is the lattice mismatch.

The lattice mismatch (Δa/a) as the variation amount of the lattice constant is proportional to the concentration of impurities N. However, the proportionality coefficient β differs depending on the impurities, as described in “Property of Crystalline Silicon”, Inspec/Iee January 2000, ISBN:0852969333), which indicates that, for example, if boron is used as an acceptor and phosphorus is used as a donor, the data shown in Table 1 is obtained.

TABLE 1

| impurities | β(cm³/atom) |
|---|---|
| boron | −5.46 × 10⁻²⁴ |
| phosphorus | −7.20 × 10⁻²⁵, −1.00 × 10⁻²⁴, −1.80 × 10⁻²⁴ |

As shown in this scheme with boron and phosphorus as a dopant, β has a negative value and decreases the lattice constant. That is, when a dopant such as a donor or an acceptor is doped and the atomic radius of the dopant (As, Ge, Sb, etc.) is greater than the atomic radius of silicon (1.17 Å), the lattice constant of the silicon crystal which includes such a dopant tends to increase.

On the other hand, if the atomic radius of a dopant (B, P) is smaller than the atomic radius of silicon (1.17 Å), then the lattice constant of the silicon crystal which includes such a dopant tends to decrease.

These phenomena also occur in an epitaxial layer obtained by epitaxial growth as well as in a silicon substrate doped with a dopant. For this reason, it is necessary to increase the lattice constant of the silicon epitaxial layer in order to reduce the misfit dislocations when using an atomic element whose atomic radius is smaller than that of silicon (1.17 Å) for the silicon epitaxial layer as an acceptor or a donor. In this case, an atomic element with a greater atomic radius than that of silicon is used as a lattice constant adjusting material.

On the other hand, when using an atomic element whose atomic radius is greater than that of silicon (1.17 Å) for the silicon epitaxial layer as an acceptor or a donor, it is necessary to decrease the lattice constant of the silicon epitaxial layer. An element with a smaller atomic radius than that of silicon (an element that reduces the lattice constant of silicon) is used as a lattice constant adjusting material in this case.

If the lattice constant adjusting material relevant to the present invention is used for increasing the lattice constant of silicon, the lattice constant adjusting material is preferably an element whose atomic radius is greater than that of silicon and which does not change the resistance of the epitaxial layers (the first and third layers). A compound containing germanium or tin is especially preferable. A compound containing germanium is even more preferable.

If the lattice constant adjusting material relevant to the present invention is used for decreasing the lattice constant of silicon, the lattice constant adjusting material is preferably a material whose atomic radius is smaller than that of silicon and which does not change the resistance of the epitaxial layer (the first and third).

The epitaxial layer (the first and third) relevant to the present invention can be doped with arsenic instead of phosphorus. The β value for arsenic is not exactly known, but it is known to be very small. Thus, it is not necessary to dope germanium when doping arsenic.

When doping a lattice constant adjusting material relevant to the present invention, either the element itself or a compound containing the element can be used.

Doping with germanium is effective when utilizing boron as an acceptor for the silicon epitaxial layer and/or utilizing phosphorus as a donor, whereby the effect of decreasing the lattice constant of silicon can be offset. Also, the lattice constant of germanium is greater by 4.2% than that of silicon. A simple approximation according to the Vegard's law teaches that β_{Ge} is about +8.4×10⁻²⁵ cm³/atom, and that its absolute value is almost the same as that of phosphorus but with its sign reversed. By controlling the germanium concentration doped into the epitaxial layer relevant to the present invention, Δa/a can be rendered closer to zero.

Here, the concentration of each donor in the silicon epitaxial layer is defined as [X]_{Dk}, its β value as β_{Dk}, the concentration of each acceptor as [X]_{Ak}, its β value as β_{Ak}, the β value of the lattice constant adjusting material as β_{Y}, and the concentration of the lattice constant adjusting material as [Y]. By controlling according to Equation 2 below, the degree of lattice mismatch (Δa/a) within the system disappears and misfit dislocations do not occur.

β_{Y}×[Y]+Σβ_{Dk}×[X]_{Dk}+Σβ_{Ak}×[X]_{Ak}=0 Equation (2)

One of either phosphorus or boron is used as a donor or an acceptor for example. The concentration of boron or phosphorus is defined as [X], its β value as β_{X}, the concentration of germanium as [Ge], its β value as β_{Ge}. It should be preferably controlled according to the value indicated in Equation (2-2) below.

β_{Ge}×[Ge]+βₓ×[X]=0 Equation (2-2)

On the other hand, the lattice of the epitaxial layer can be deformed in case of coherent growth as stated above if the epitaxial layer is thin enough. Therefore, the occurrence of misfit dislocations also depends on the thickness of layers. The detail is described in “J. W. Matthews, A. E. Blakeslee J. CRYST. GROWTH (Netherlands) vol. 27 (1974) p. 118; vol. 29 (1975) p. 2′73; vol. 32 (1976) p. 265”.

Thus, misfit dislocations may not occur even though Equations (2) or (2-2) are not satisfied if the layer is thin. According to the inventors' findings, it was confirmed that the misfit dislocation does not occur if Equation (3) is satisfied.

β_{Y}×[Y]+Σβ_{Dk}×[X]_{Dk}+Σβ_{Ak}×[X]_{Ak}<γ Equation (3)

wherein “γ” is dimensionless number which is called as critical lattice mismatch (or critical distortion).

β_{Y}×[Y] is the value Δa_{y}/a_{Si} which is obtained by dividing the variation of the lattice constant (Δa_{y}) in doping a lattice constant adjusting material into the silicon single crystal by the lattice constant (a_{Si}) of the silicon single crystal in Equation (3) above.

β_{Dk}x[X]_{Dk} is the value Δa_{Dk}/a_{Si} which is obtained by dividing the variation of the lattice constant (Δa_{Dk}) in doping various donors into the silicon single crystal by the lattice constant (a_{Si}) of the silicon single crystal likewise.

β_{Ak}×[X]_{Ak} is the value Δa_{A}/a_{Si} which is obtained by dividing the variation of the lattice constant (Δa_{Ak}) in doping various acceptors into the silicon single crystal by the lattice constant (a_{Si}) of the silicon single crystal.

Therefore, the left side of Equation (3) is obtained by dividing the sum of the variations of the lattice constants in doping the silicon single crystal with the lattice constant adjusting material, each donor, and each acceptor individually by the lattice constant of the silicon single crystal.

On the other hand, when doping the lattice constant adjusting material, each donor, and each acceptor into the silicon epitaxial layer at the same time, the variation of the lattice constant can be obtained by summing up the variations of the lattice constant, which are caused by doping the lattice constant adjusting material, each donor, and each acceptor individually into the silicon single crystal.

Therefore, it is understood that the variation of the lattice constant in the first epitaxial layer relevant to the present invention, which is Δa_{1-Si} (a₁-a_{Si}), is equal to the left side of the above Equation (3) multiplied by the lattice constant of the silicon single crystal for example.

The variation of the lattice constant of the second and third epitaxial layers relevant to the present invention can be considered likewise.

When either phosphorus or boron is used as a donor or an acceptor and germanium is used as a lattice constant adjusting material as in the above Equation (2-2), the following Equation (3-2) results.

β_{Ge}×[Ge]+βₓ×[X]<γ Equation (3-2)

wherein “γ” is dimensionless number which is called the critical lattice mismatch (or critical distortion). The γ in the above equation is a function of the layer thickness of the epitaxial layer.

By measuring γ corresponding to a thickness in advance, a proper value can easily be obtained. According to the inventors' findings, γ can be described by the following Equation (4) with T (μm) being the thickness of the epitaxial layer.

Log(γ)=−1.11×Log(T)−3.84 Equation (4)

In this regard, “Log” is the common logarithm.

The preferable embodiments of the present invention will be explained below referring to the figures.

FIG. 2 is a schematic cross-section diagram showing an example of a semiconductor substrate according to another preferable embodiment of the present invention. First, a silicon wafer relevant to the present invention can be formed by the following process as shown in FIG. 2. A third p-type epitaxial layer 13 which contains a lattice constant adjusting material as well as a donor and/or an acceptor is grown on a silicon substrate (e.g. nondoped, n-type or p-type silicon single crystal) 10 by the epitaxial growth method. Next, a first n-type epitaxial layer 11 which contains a lattice constant adjusting material as well as a donor and/or an acceptor is grown on the third epitaxial layer 13 by the epitaxial growth method. A second epitaxial layer 12 which contains a donor and/or an acceptor with the same conductivity type as the first epitaxial layer 11 is grown on the first epitaxial layer 11.

Heat treatment can be alternatively performed after depositing the third epitaxial layer, the first epitaxial layer, and the second epitaxial layer on the silicon substrate, respectively, as stated above.

The silicon substrate relevant to the present invention is not particularly limited, as long as its resistivity is greater than or equal to 0.1 Ω.cm. The resistivity is preferably within 1 Ω.cm to 100 Ω.cm. The silicon substrate production method relevant to the present invention can be performed by a conventionally known method such as the Czochralski method or the FZ method. It would not matter if the silicon substrate is produced by the wafer product manufacturer or obtained as a commercialized product, or if it is n-type or p-type, and may utilize a silicon crystal which contains hydrogen, nitrogen, and carbon.

The method of doping nitrogen, hydrogen, or carbon into a silicon crystal (or a silicon substrate formed by cutting out a grown silicon crystal) is not particularly limited. Any conventional method can be used. More specifically, by adding silicon substrates with a nitride film into a melt from which a silicon crystal is grown, the nitrogen concentration in the silicon substrate can be controlled. The hydrogen concentration can be controlled by injecting a gas containing hydrogen to the furnace. The carbon concentration of the silicon substrate wafer can be controlled by doping carbon powders into the melt in which the silicon crystal is grown.

The first epitaxial layer relevant to the present invention is preferably a silicon epitaxial layer doped with a dopant and a lattice constant adjusting material. The first epitaxial layer contains silicon as a main ingredient. The first epitaxial layer comprises the following: at least one substance selected from the group of donor elements as a dopant, for example an element in group 13 such as boron, or any known dopant containing such an element, and acceptor elements, for example an element in group 15 such as phosphorus or arsenic, or any known dopant containing a such element; and a lattice constant adjusting material.

If both a donor and an acceptor are contained as dopants, it is preferred that the absolute value of the difference between the donor concentration and the acceptor concentration is greater than or equal to 1×10¹⁸ atoms/cm³ and less than or equal to 1×10²⁰ atoms/cm³.

The same concentration range is applied when either a donor or an acceptor is contained in the first epitaxial layer. In addition, the composition ratio of the above-described constituents for the first epitaxial layer is controlled according to Equation (3).

The thickness of the first epitaxial layer is preferably not more than 10 μm, and more preferably not less than 1 μm and not more than 5 μm. If the thickness is less than or equal to 10 μm, misfit dislocations can be suppressed or prevented since it is less than the critical thickness of an epitaxial layer.

The second epitaxial layer relevant to the present invention is preferably a silicon epitaxial layer doped with a dopant. The second epitaxial layer contains silicon as a major component. The second epitaxial layer comprises the following: at least one substance selected from the group of donor elements as a dopant, for example an element in group 13 such as boron, or any known dopant containing a such element, and acceptor elements, for example an element in group 15 such as phosphorus and arsenic, or any known dopant containing a such element.

If both a donor and an acceptor are contained as a dopant, it is preferred that the absolute value of the difference between the donor concentration and the acceptor concentration is less than or equal to 5×10¹⁷ atoms/cm³.

The same concentration range is applied when either a donor or an acceptor is contained. In addition, the composition ratio of the above-described constituents for the second epitaxial layer is controlled according to Equation (3).

The third epitaxial layer relevant to the present invention is preferably a silicon epitaxial layer doped with an acceptor and a lattice constant adjusting material. The third epitaxial layer contains silicon as a major component. The third epitaxial layer contains, as an acceptor, an element in the group 13 such as boron, or any known dopant containing a such element, as well as a lattice constant adjusting material. If both a donor and acceptor are included as a dopant, it is preferred that the absolute value of the difference between the donor concentration and the acceptor concentration is greater than or equal to 1×10¹⁸ atoms/cm³ and less than or equal to 1×10²⁰ atoms/cm³.

The same concentration range is applied when either a donor or an acceptor is contained. In addition, the composition ratio of the above-described constituents for the third epitaxial layer is controlled according to Equation (3).

The thickness of the third epitaxial layer is preferably not more than 20 μm, and more preferably not less than 1 μm and not more than 10 μm. If its thickness is less than or equal to 20 μm, it is less than the critical film thickness, and thus misfit dislocations can be suppressed and prevented.

The first, the second, and the third epitaxial layers relevant to the present invention can be fabricated by means of CVD (Chemical Vapor Deposition) or MBE (Molecular Beam Epitaxy). There is no restriction on the method by which those layers are fabricated.

If a CVD process is chosen for example, any known source gas can be used. The choice of a source gas is not limited. A source gas can be, for example, any of the following: SiHCl₃, SiH₄, SiH₂Cl₂, etc. for the silicon element; B₂H₆ etc. for the boron element if boron is used as an acceptor; PH₃ etc. for the phosphorus element if phosphorus is used as an acceptor; GeH₄, GeCl₄, etc. if germanium is used as a lattice constant adjusting material; or any mixed gas. H₂ can be used as a carrier gas. The growth condition is not specifically limited and can be chosen arbitrarily.

A temperature of 700-1100° C. and a pressure of 100 Pa to the normal pressure can suitably be used.

Examples of the preferable embodiments of the silicon wafer relevant to the present invention will be explained hereafter.

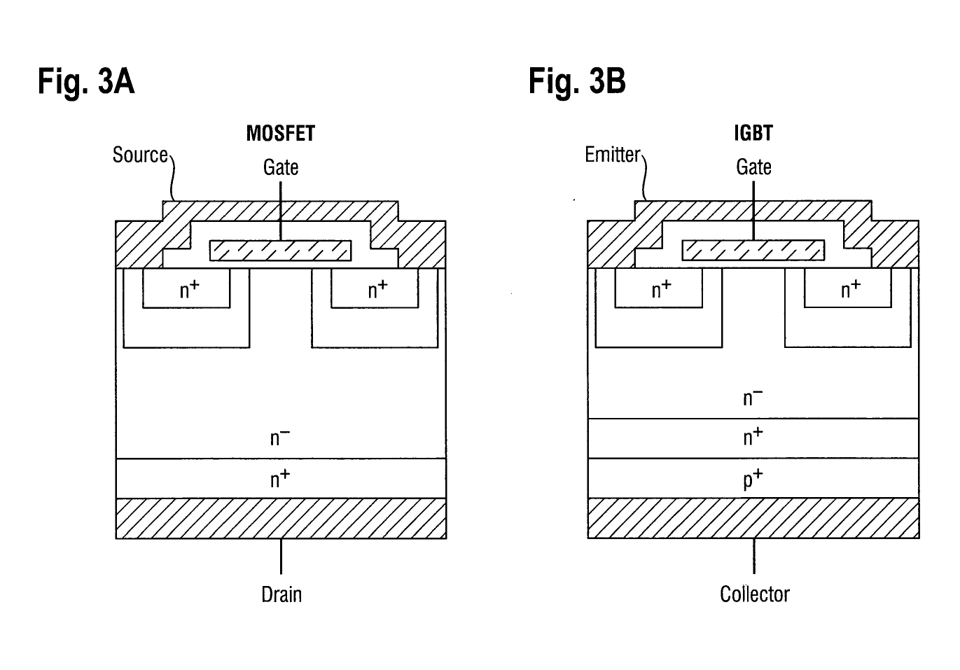

A case in which a wafer relevant to the present invention is applied to an n-type or a p-type power MOSFET as shown in FIG. 3(A) will be explained below as an example.

A silicon wafer is produced by the Czochralski method for example, as described above. This wafer should preferably have a resistivity of greater than or equal to 0.1 Ω.cm and could be n-type, p-type, or nondoped. That is, for the epitaxial layer used as a drift layer of a power MOSFET, the lattice mismatch should be low enough not to cause any problems.

According to the findings of the inventors, it was confirmed that misfit dislocations can be successfully prevented and the warpage does not worsen when the variation ratio of the lattice constant, ((a₁-a_{Si})/a_{Si}), is controlled less than about 1×10⁻⁵.

A first epitaxial layer highly doped with a dopant (a donor and/or an acceptor) is subsequently formed on the silicon substrate. This epitaxial layer is a layer corresponding to a drain electrode. Thus, an impurity or a dopant is doped with a concentration of greater than or equal to 1×10¹⁹ atoms/cm³ in many cases. Therefore, the lattice constant is varied compared to when a silicon substrate, especially a nondoped silicon substrate, is used.

After the first epitaxial layer is formed, a second epitaxial layer doped in a low concentration is formed. This second epitaxial layer contains a relatively low impurity concentration since it is used for the drift layer of a power device. The concentration of an impurity or a dopant is generally less than or equal to 5×10¹⁷ atoms/cm³, and the variation in the lattice constant is negligible. It is not necessary to dope a lattice constant adjusting material such as germanium in contrast to a highly doped layer such as the first epitaxial layer.

A case in which a wafer relevant to the present invention is applied to a punch through IGBT as shown in FIG. 3(B) will be explained as an example hereafter.

A silicon substrate is produced as described above, thereafter, a p-type third epitaxial layer into which boron is doped with the concentration not less than 1×10¹⁸ atoms/cm³ and not more than 1×10²° atoms/cm³ is formed. This layer corresponds to a collector of an IGBT. Then, an n-type first epitaxial layer into which phosphorus or arsenic is doped with the concentration not less than 1×10¹⁷ atoms/cm³ and not more than 1×10¹⁹ atoms/cm³ is formed. This layer corresponds to a field stop layer of a depletion layer.

The above-described p-type or n-type, highly doped layer may possibly be prone to misfit dislocations, depending on its concentration.

A lattice constant adjusting material such as germanium is doped into the first and the third epitaxial layer in accordance with the above Equation (3) if necessary. An n-type layer (the second epitaxial layer) into which phosphorus or arsenic is further doped with the concentration not less than 1×10¹³ atoms/cm³ and not more than 1×10¹⁵ atoms/cm³ is formed. This n-type layer corresponds to a base of a bipolar device. This n-type layer is generally lightly doped as described above, and thus it is not necessary to dope a lattice constant adjusting material such as germanium.

Examples of the present invention will be explained hereafter. However, the present invention is not limited to below-mentioned Examples. That is, Examples mentioned below are meant to be exemplary only. Anything having substantially the same configuration as the technical spirit described in the claims of the present invention and anything having the similar function effect are considered to be within the technical range of the present invention.

### Example 1

Mirror wafers were produced by slicing an n-type, Czochralski-grown silicon single crystal ingot with a diameter of 200 mm and a phosphorus concentration of 5×10¹⁴ atoms/cm³ and by subjecting the sliced wafers to a wafer production process.

Next, the wafers were introduced into a single-loading type device for growing epitaxial vapor-phase by a lamp-heating method, and subjected to a 1100° C. hydrogen atmosphere for heat treatment for cleaning.

Then, a mixed reactant gas of SiHCl₃, GeCl₄, and PH₃ was supplied at 1050° C. and normal pressure. A first epitaxial layer with a donor concentration (phosphorus concentration) of 7×10¹⁹ atoms/cm³ as well as a lattice constant adjusting material (germanium concentration) of 9×10¹⁹ atoms/cm³ was grown in 10 μm thickness on the wafer through the CVD process. The germanium concentration and the phosphorus concentration of the first epitaxial layer were measured by SIMS (Secondary Ion Mass Spectroscopy).

In order to control the germanium concentration and the phosphorus concentration for the first epitaxial layer, the concentration of PH₃ gas or GeCl₄ gas can be altered, or their flows can be altered alternatively. It took 5 minutes to grow the first epitaxial layer of 10 μm thickness.

Next, a second epitaxial layer with a donor concentration (phosphorus concentration) of 1×10¹⁴ atoms/cm³ was grown on the first epitaxial layer in 50 μm thickness through the CVD process at 1150° C. and normal pressure. It took 20 minutes for this process.

After growing the epitaxial layers, the above-mentioned wafer was subjected to heat treatment in an Argon atmosphere at 1100° C. for 1 hour.

The occurrence of misfit dislocations in the resulting wafer was investigated using an X-ray topography device, and it was confirmed that there was no occurrence of misfit dislocations.

### Example 2

Mirror wafers were produced by slicing an n-type, Czochralski-grown silicon single crystal ingot with a diameter of 200 mm and a phosphorus concentration of 5×10¹⁴ atoms/cm³ and by subjecting the sliced wafers to a wafer production process.

Then, the wafers were set in a single wafer, lamp-heated epitaxial vapor-phase growth device and subjected to a 1100° C. hydrogen atmosphere for heat treatment.

Next, a mixed reactant gas of SiHCl₃, GeCl₄, and B₂H₆ was supplied at 1050° C. and normal pressure. A third epitaxial layer (p-type) with the acceptor concentration (boron concentration) of 5×10¹⁹ atoms/cm³ as well as a lattice constant adjusting material (germanium concentration) of 3.3×10²⁰ atoms/cm³ was grown in 10 μm thickness on the wafer through the CVD process.

In order to control the germanium concentration and the boron concentration for the third epitaxial layer, the concentration of B₂H₆ gas or GeCl₄ gas, can be altered, or their flows can be altered alternatively. It took 5 minutes to grow the 10 μm thick, third epitaxial layer.

Then, a mixed reactant gas of SiHCl₃, GeCl₄, and PH₃ was supplied at 1150° C. and normal pressure. A first epitaxial layer with the donor concentration (phosphorus concentration) of 1×10¹⁹ atoms/cm³ as well as a lattice constant adjusting material (germanium concentration) of 1×10¹⁹ atoms/cm³ was grown in 10 μm thickness on the third epitaxial layer through the CVD process. It took 5 minutes for this growing process.

Then, a mixed reactant gas of SiHCl₃ and PH₃ was supplied at 1150° C. and normal pressure. A second epitaxial layer with the donor concentration (phosphorus concentration) of 1×10¹⁴ atoms/cm³ was grown in 50 μm thickness on the first epitaxial layer through the CVD process. It took 20 minutes for this growing process.

After growing the epitaxial layers, the above-mentioned wafer was subjected to heat treatment in an Argon atmosphere with 1100° C. for 1 hour.

The occurrence of misfit dislocations in the resulting wafer was investigated using X-ray topography and it was confirmed that there was no occurrence of misfit dislocations.

### Comparative Example 1

Mirror wafers were produced by slicing an n-type, Czochralski-grown silicon single crystal ingot with a diameter of 200 mm and a phosphorus concentration of 5×10¹⁴ atoms/cm³ and by subjecting the sliced wafers to a wafer production process.

Then, the wafers were placed in a single wafer, lamp-heated epitaxial vapor-phase growth device and subjected to a 1100° C. hydrogen atmosphere for heat treatment.

Next, a mixed reactant gas of SiHCl₃ and PH₃ was supplied at 1150° C. and normal pressure. A highly doped epitaxial layer with the donor concentration (phosphorus concentration) of 7×10¹⁹ atoms/cm³ was grown in 10 μm thickness on the wafer through the CVD process. The concentration of this highly doped epitaxial layer was measured by SIMS as described above.

Next, a lightly doped layer with the donor concentration (phosphorus concentration) of 1×10¹⁴ atoms/cm³ was grown on the above highly doped epitaxial layer in 50 μm thickness through the CVD process at 1150° C. and normal pressure. It took 20 minutes for this growing process.

After growing the epitaxial layers, the above wafer was subjected to heat treatment in an Argon atmosphere at 1100° C. for 1 hour.

The occurrence of misfit dislocations in the resulting wafer was investigated using X-ray topography, and it was confirmed that there was an occurrence of misfit dislocations over almost all of the wafer.

### Comparative Example 2

Mirror wafers were produced by slicing an n-type, Czochralski-grown silicon single crystal ingot with a diameter of 200 mm and a phosphorus concentration of 5×10¹⁴ atoms/cm³ and by subjecting the sliced wafers to a wafer production process.

Next, the wafers were placed in the single wafer, lamp-heated epitaxial vapor-phase growth device and subjected to a 1100° C. hydrogen atmosphere for heat treatment.

Then, a mixed reactant gas of SiHCl₃ and B₂H₆ was supplied at 1150° C. and normal pressure. A p-type highly doped epitaxial layer with the acceptor concentration (boron concentration) of 5×10¹⁹ atoms/cm³ was grown in 10 μm thickness on the wafer through the CVD process.

In order to control the germanium concentration and the boron concentration for the p-type highly doped epitaxial layer, the concentration of B₂H₆ gas or GeCl₄ gas can be altered, or their flows can be altered alternatively. It took 5 minutes to grow the 10 μm thick, p-type highly doped epitaxial layer.

Then, a mixed reactant gas of SiHCl₃ and PH₃ was supplied at 1150° C. and normal pressure. An n-type highly doped epitaxial layer with the donor concentration (phosphorus concentration) of 1×10¹⁹ atoms/cm³ was grown in 10 μm thickness on the p-type highly doped epitaxial layer through the CVD process. It took 5 minutes for this growing process.

Then, a mixed reactant gas of SiHCl₃, and PH₃ was supplied at 1150° C. and normal pressure. A lightly doped epitaxial layer with the donor concentration (phosphorus concentration) of 1×10¹⁴ atoms/cm³ was grown in 50 μm thickness on the n-type highly doped epitaxial layer through the CVD process. It took 20 minutes for this growing process.

After growing the epitaxial layers, the above-mentioned wafer was subjected to heat treatment in an Argon atmosphere with 1100° C. for 1 hour.

The occurrence of misfit dislocations in the resulted wafer was investigated using X-ray topography, and it was confirmed that there was an occurrence of misfit dislocations over almost all of the wafer.

The data on the resistivity of Examples and Comparative Examples and the variation amount of the lattice constants of each epitaxial layer are summarized in Table 2 below.

TABLE 2

| | SR | Dif 1 | | Dif 2 | | Dif 3 | |
|---|---|---|---|---|---|---|---|
| | (Ω cm) | (atoms/cm³) | ((a₁₋aₛᵢ)/aₛᵢ) | (atoms/cm³) | ((a₂₋aₛᵢ)/aₛᵢ) | (atoms/cm³) | ((a₃₋aₛᵢ)/aₛᵢ) |
| Ex. 1 | 8.8 | 7.00 × 10¹⁹ | −9.96 × 10⁻⁶ | 1.00 × 10¹⁴ | −1.20 × 10⁻¹⁰ | | |
| Ex. 2 | 8.8 | 1.00 × 10¹⁹ | 8.20 × 10⁻⁶ | 1.00 × 10¹⁴ | −1.20 × 10⁻¹⁰ | 5.00 × 10¹⁹ | −2.4 × 10⁻⁶ |
| Comp. | 8.8 | 7.00 × 10¹⁹ | −8.40 × 10⁻⁵ | 1.00 × 10¹⁴ | −1.20 × 10⁻¹⁰ | | |
| Ex. 1 | | | | | | | |
| Comp. | 8.8 | 5.00 × 10¹⁹ | −2.73 × 10⁻⁴ | 1.00 × 10¹⁴ | −1.20 × 10⁻¹⁰ | 1.00 × 10¹⁹ | |
| Ex. 2 | | | | | | | |

SR: substrate resistivity
Dif 1: Absolute value of difference between donor concentration and acceptor concentration in the first epitaxial layer ((a₁₋aₛᵢ)/aₛᵢ): Variation amount of lattice constant in the first epitaxial layer
Dif 2: Absolute value of difference between donor concentration and acceptor concentration in the second epitaxial layer ((a₂₋aₛᵢ)/aₛᵢ): Variation amount of lattice constant in the second epitaxial layer
Dif 3: Absolute value of difference between donor concentration and acceptor concentration in the third epitaxial layer ((a₃₋aₛᵢ)/aₛᵢ): Variation amount of lattice constant in the third epitaxial layer

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

What is claimed is:

1. A silicon wafer comprising:
a silicon substrate having a resistivity of greater than or equal to 0.1 Ω.cm;
a first epitaxial layer having a conductivity type, provided on a surface of said silicon wafer, wherein an absolute value of the difference between a donor concentration and an acceptor concentration is greater than or equal to 1×10¹⁸ atoms/cm³; and
a second epitaxial layer provided on said first epitaxial layer, said second epitaxial layer having the same conductivity type as said first epitaxial layer, wherein an absolute value of the difference between a donor concentration and an acceptor concentration is less than or equal to 5×10¹⁷ atoms/cm³;
wherein, by doping a lattice constant adjusting material into said first epitaxial layer, a variation amount ((a₁-a_{Si})/a_{Si}) of a lattice constant of said first epitaxial layer (a₁) relative to a lattice constant of a silicon single crystal (a_{Si}) and a variation amount ((a₂-a_{Si})/a_{Si}) of a lattice constant of said second epitaxial layer (a₂) relative to the lattice constant of the silicon single crystal (a_{Si}) are controlled to less than a critical lattice mismatch.

2. The silicon wafer of claim 1, wherein
said critical lattice mismatch is expressed by Equation (4):
Log(γ)=−1.11×Log(T)−3.84 Equation (4)
where γ is said critical lattice mismatch and T is a thickness of the first or second epitaxial layer.

3. The silicon wafer of claim 1, wherein said lattice constant adjusting material comprises a compound containing germanium.

4. The silicon wafer of claim 2, wherein said lattice constant adjusting material comprises a compound containing germanium.

5. The silicon wafer of claim 1, further comprising a p-type third epitaxial layer between said first epitaxial layer and said silicon substrate, with an acceptor concentration of said third epitaxial layer being greater than or equal to 1×10¹⁸ atoms/cm³, wherein said conductivity type of said first and second epitaxial layers is n-type, and wherein, by doping said lattice constant adjusting material into said first and third epitaxial layers, a variation amount ((a₃-a_{Si})/a_{Si}) of a lattice constant of said third epitaxial layer (a₃) relative to the lattice constant of the silicon single crystal (a_{Si}) are controlled to less than the critical lattice mismatch.

6. The silicon wafer of claim 2, further comprising a p-type third epitaxial layer between said first epitaxial layer and said silicon substrate, with an acceptor concentration of said third epitaxial layer being greater than or equal to 1×10¹⁸ atoms/cm³, wherein said conductivity type of said first and second epitaxial layers is n-type, and wherein, by doping said lattice constant adjusting material into said first and third epitaxial layers, a variation amount ((a₃-a_{Si})/a_{Si}) of a lattice constant of said third epitaxial layer (a₃) relative to the lattice constant of the silicon single crystal (a_{Si}) are controlled to less than the critical lattice mismatch.

7. The silicon wafer of claim 3, further comprising a p-type third epitaxial layer between said first epitaxial layer and said silicon substrate, with an acceptor concentration of said third epitaxial layer being greater than or equal to 1×10¹⁸ atoms/cm³, wherein said conductivity type of said first and second epitaxial layers is n-type, and wherein, by doping said lattice constant adjusting material into said first and third epitaxial layers, a variation amount ((a₃-a_{Si})/a_{Si}) of a lattice constant of said third epitaxial layer (a₃) relative to the lattice constant of the silicon single crystal (a_{Si}) are controlled to less than the critical lattice mismatch.

8. The silicon wafer of claim 4, further comprising a p-type third epitaxial layer between said first epitaxial layer and said silicon substrate, with an acceptor concentration of said third epitaxial layer being greater than or equal to 1×10¹⁸ atoms/cm³, wherein said conductivity type of said first and second epitaxial layers is n-type, and wherein, by doping said lattice constant adjusting material into said first and third epitaxial layers, a variation amount ((a₃-a_{Si})/a_{Si}) of a lattice constant of said third epitaxial layer (a₃) relative to the lattice constant of the silicon single crystal (a_{Si}) are controlled to less than the critical lattice mismatch.
